(19) United States
(12) Patent Application Publication
(10) Pub. No.: US 2009/0101197 A1
(43) Pub. Date: Apr. 23, 2009

(54) Solar Battery and Production Method Thereof

(75) Inventor: Hiroaki Morikawa, Tokyo (JP)

Correspondence Address: BUCHANAN, INGERSOLL & ROONEY PC, POST OFFICE BOX 1404, ALEXANDRIA, VA, 22313-1404, US

(73) Assignee: MITSUBISHI ELECTRIC CORPORATION, Tokyo (JP)

(21) Appl. No.: 11/920,154

(22) PCT Filed: May 11, 2005
(86) PCT No.: PCT/JP2005/008602

§ 371 Date: Nov. 9, 2007

(51) Int. Cl. H01L 31/00; H01L 21/4763

(52) U.S. Cl. 136/252; 438/24; 257/E21.495

(57) ABSTRACT

Included are a semiconductor layer that is formed on a light receiving surface of a semiconductor substrate and is of a type opposite to that of said semiconductor substrate, an electrode of a semiconductor layer that is of the same type as that of the semiconductor layer of said light receiving surface and is formed on a rear surface opposite to said light receiving surface, an electrode that is of the same type as that of said semiconductor substrate and is electrically insulated from said electrode of the semiconductor layer of the same type as that of the semiconductor layer of said light receiving surface formed on said rear surface, and a semiconductor layer that is of the same type as that of the semiconductor layer of said light receiving surface and electrically connects between the semiconductor layer of said light receiving surface and said electrode of the semiconductor layer of the same type as that of the semiconductor layer of said light receiving surface formed on said rear surface.

### TECHNICAL FIELD

The present invention relates to a solar battery of a wraparound structure in which electrodes are not arranged at a light receiving surface side thereof, and also to a method of producing the same.

### BACKGROUND ART

A conventional solar battery is composed of an n type diffusion layer that is formed on a front surface of a p type silicon substrate, a p+ type diffusion layer that is formed on a rear surface of the p type silicon substrate in a region of the n type diffusion layer which is insulated in an island-like fashion, a p type layer electrode that is formed on the p+ type diffusion layer of the rear surface of the p type silicon substrate, and an n type layer electrode that is formed on the n type diffusion layer on a light receiving surface of the p type silicon substrate (see, for example, a first patent document).

However, when the n type layer electrode is arranged on the light receiving surface of the p type silicon substrate, there arises a problem that an actual area loss of a light incident plane becomes 8 to 10%. Accordingly, there has been proposed a solar battery of a wraparound structure which is constructed as follows. That is, after formation of a polycrystalline silicon thin film on a thermal resistance substrate, through holes arranged in a grid-like fashion is formed in a semiconductor thin film, which is obtained by applying a zone melting recrystallization process to the polycrystalline silicon thin film, by means of anisotropic etching, and then the semiconductor thin film is separated or peeled off from the thermal resistance substrate to form an n type diffusion layer on a surface of the semiconductor thin film. This n type diffusion layer is also formed on a side wall of each through hole, so a light receiving surface of the semiconductor thin film and an n type diffusion layer on the rear surface thereof are made conductive through the n type diffusion layer on the side wall of each through hole. Then, leaving part of the n type diffusion layer of the rear surface formed on the side surface of each through hole, the remainder of the n type diffusion layer is removed until a p type semiconductor thin film appears on its surface. An n type layer electrode is formed on the n type diffusion layer formed on the side surface of each through hole, and at the same time, a p type layer electrode is formed on the semiconductor thin film that has appeared by the removal of the n type diffusion layer, thereby producing the solar battery with no electrode arranged on a light receiving surface (see, for example, a second patent document).

First patent document: Japanese patent application laid-open No. H5-75148

Second patent document: Japanese patent application laid-open No. H7-226528

### DISCLOSURE OF THE INVENTION

### Problems to be Solved by the Invention

However, in order to draw out the n type layer electrode from the n type diffusion layer of the rear surface that is conducted to the n type diffusion layer of the light receiving surface through the n type diffusion layer on the side wall of each of the through holes arranged in a grid-like fashion in the semiconductor thin film, there is required the semiconductor thin film which is so thin as to be able to form the through holes by the anisotropic etching. To this end, it is necessary to laminate a separation or peeling layer comprising a silicon oxide film, a polycrystalline silicon thin film, and a cap layer comprising a silicon nitride film on a thermal resistance substrate, to apply a zone melting recrystallization process thereto, to remove the cap layer, and to epitaxially grow a polycrystalline silicon thin film thereon. Thus, there is a problem that this results in too many number of process steps and hence too much cost.

In addition, in the anisotropic etching that forms the through holes in the grid-like fashion, the etching proceeds along a [111] surface azimuth, so there is a problem that if a through hole of a columnar shape is intended to be formed, one of a truncated pyramid results.

In addition, the semiconductor thin film is a polycrystalline material, so the individual surface azimuths of crystal grains do not align with respect to one another. Thus, there is the following problem. That is, if the through holes are formed at positions astride crystal grain boundaries, the configurations of the through holes thus formed become uneven, so when the n type diffusion layer except in regions formed on the side surfaces of the through holes is removed from the rear surface, the through holes extend to the regions to be removed because of the uneven configurations thereof.

In addition, the etching proceeds along the [111] surface azimuths, so the opening area of each through hole on the rear surface becomes smaller than the opening area thereof on the light receiving surface. Accordingly, there is also the following problem. That is, in order to satisfy an electrical characteristic that makes the light receiving surface and the rear surface conductive to each other through the n type diffusion layers of the side walls of the through holes, it is necessary to make the opening area of each through hole on the rear surface larger than a predetermined value, so the opening area of each through hole on the light receiving surface becomes large, thus resulting in an increase in the actual area loss of a light incident plane.

Further, partially leaving the n type diffusion layer in a region enclosing the opening portion of each through hole on the rear surface, the n type diffusion layer in the remaining region is removed, so that an n type layer electrode is formed on each left portion of the n type diffusion layer, and at the same time, a p type layer electrode is formed in the region where the n type diffusion layer has been removed. However, it is necessary to perform a plurality of position adjustments for screen printing, etc., so as to form a resist film for the removal of the n type diffusion layer, and to form the n type layer electrode and the p type layer electrode. As a result, there is a problem that a lot of time is required for the position adjustment.

The object of the present invention is to provide a solar battery of a wraparound structure in which no electrode is arranged on a light receiving surface composed of a semiconductor substrate of which the thickness is not particularly thin, and also to provide a method of producing the same.

### Means for Solving the Problem

A solar battery according to the present invention includes: first semiconductor layer that is formed on a light receiving surface of a semiconductor substrate, and is of a type opposite to that of the semiconductor substrate; second semiconductor layer that is formed on a rear surface opposite to the light receiving surface, and is of the same type as that of the first semiconductor layer; an electrode of third semiconductor layer that is of the same type as that of the first semiconductor layer, and is formed on the second semiconductor layer; first electrode that is of the same type as that of the semiconductor substrate, and is directly formed on the rear surface of the semiconductor substrate so as to be electrically insulated from the electrode of the third semiconductor layer; and fourth semiconductor layer that is of the same type as that of the first semiconductor layer, and electrically connects between the first semiconductor layer and the electrode of the third semiconductor layer.

### EFFECT OF THE INVENTION

The advantageous effects of a solar battery according to the present invention are as follows. That is, the side wall of a through hole rises substantially straight and steep, so even if the thickness of the semiconductor substrate of a first electric conductivity is thick, a diffusion layer conducting between the light receiving surface and the rear surface is formed on the side wall of the through hole. As a result, it is possible to provide a solar battery of a wraparound type even without using a particularly thin semiconductor substrate.

### BRIEF DESCRIPTION OF THE DRAWINGS

FIG. 1 is a perspective view of a cell of a solar battery according to a first embodiment of the present invention.

FIG. 2 is a partial plan view of a rear surface of the solar battery cell according to the first embodiment.

FIG. 3 is an enlarged view of electrodes on the rear surface of the solar battery cell according to the first embodiment.

FIG. 4 is a partial cross sectional view of the solar battery according to the first embodiment.

FIG. 5 is cross sectional views for explaining production process steps of the solar battery cell according to the first embodiment.

FIG. 6 is an equivalent circuit diagram of the solar battery.

FIG. 7 is a view showing the relation of a diode current with respect to the pulse width of a laser beam in a grooving operation of the solar battery cell according to the first embodiment.

FIG. 8 is a partial cross sectional view of a solar battery cell according to a second embodiment of the present invention.

FIG. 9 is an enlarged view of electrodes on a rear surface of a solar battery cell according to a third embodiment.

### BEST MODE FOR CARRYING OUT THE INVENTION

### Embodiment 1

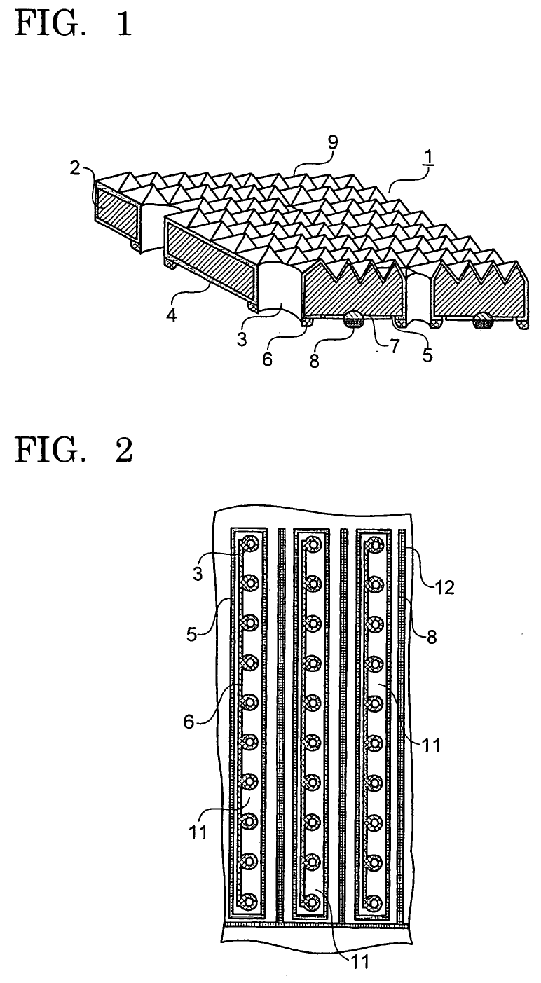

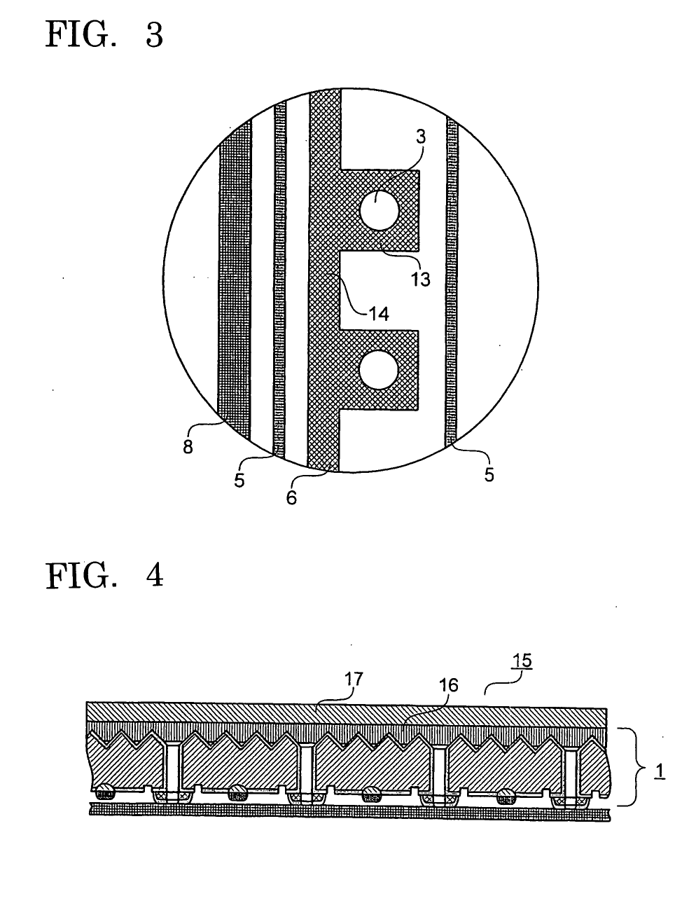

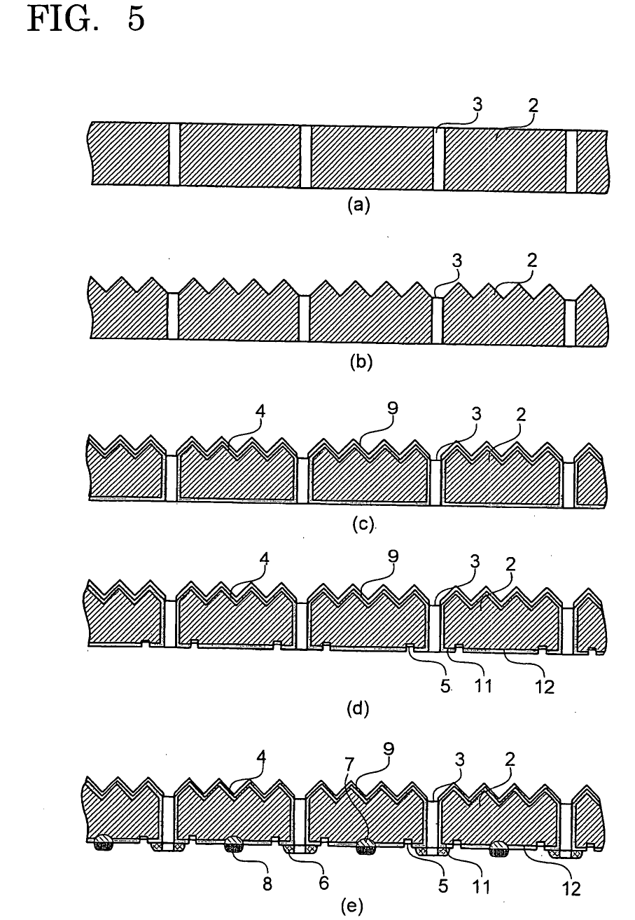

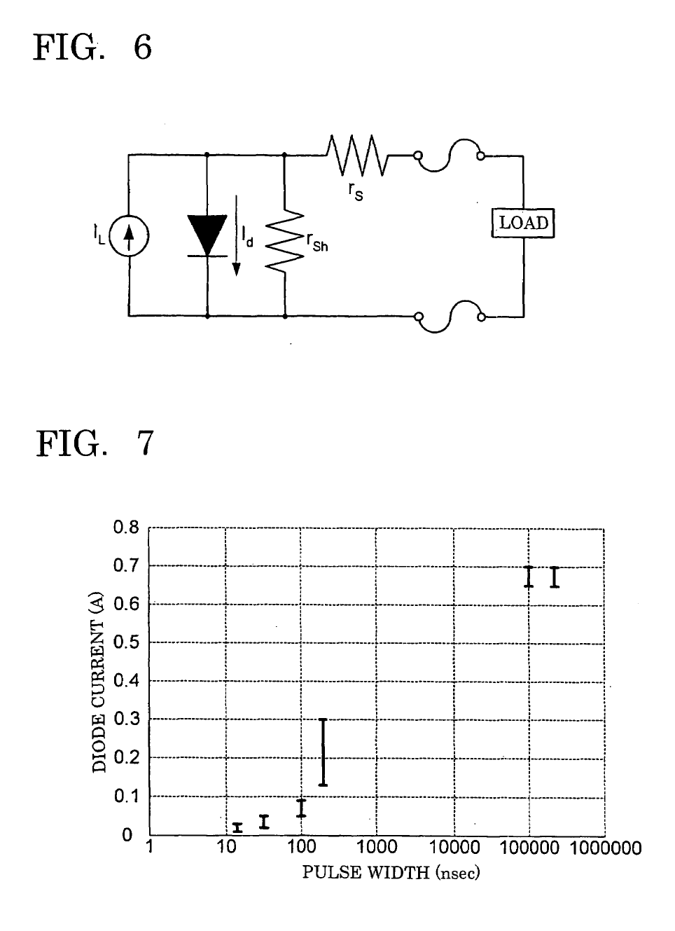

FIG. 1 is a perspective view of a cell of a solar battery according to a first embodiment of the present invention. FIG. 2 is a partial plan view of a rear surface of the solar battery cell according to the first embodiment. FIG. 3 is an enlarged view of electrodes on the rear surface of the solar battery cell according to the first embodiment. FIG. 4 is a partial cross sectional view of the solar battery according to the first embodiment. FIG. 5 is cross sectional views for explaining production process steps of the solar battery cell according to the first embodiment. FIG. 6 is an equivalent circuit diagram of the solar battery. FIG. 7 is a view showing the relation of a diode current with respect to the pulse width of a laser beam in a grooving operation of the solar battery cell according to the first embodiment.

A solar battery cell 1 according to this first embodiment is produced from a p type polycrystalline silicon substrate 2 which serves as a semiconductor substrate. Here, note that besides silicon, a gallium arsenide alloy may be used as a semiconductor that constitutes the semiconductor substrate. In addition, though the semiconductor may be of either a p type or an n type electric conductivity, explanation will be made herein of a p type silicon substrate that contains boron as a doping impurity element for the sake of convenience.

As an ingot from which the silicon substrate is cut out, there can be used a single-crystal silicon ingot made by a method such as a CZ method, an FZ method, an EFG method, etc., or a polysilicon ingot cast by a cast method. Here, note that polysilicon can be mass-produced and hence is extremely more advantageous than single-crystal silicon in terms of the production cost.

An ingot formed by such a method is sliced to a thickness of about from 50 to 200 μm, and is then cut to an outer shape in the form of a square having each side of 15 cm, whereby a p type polycrystalline silicon substrate 2 is obtained. Here, note that the doping of the silicon substrate may be carried out by making an appropriate amount of discrete doping impurity element be contained in the silicon ingot upon production thereof, or making an appropriate amount of silicon mass, the doping concentration of which is already known, be contained in the silicon ingot.

As shown in FIG. 1, the solar battery cell 1 according to the first embodiment is composed of through holes 3 that penetrate through the p type polycrystalline silicon substrate 2 in a thickness direction thereof and are arranged in a grid-like fashion, n type diffusion layers 4 that are formed on a light receiving surface and a rear surface of the p type polycrystalline silicon substrate 2 as well as on the surfaces of the side walls of the through holes 3, grooves 5 that serve to separate the n type diffusion layer 4 on the rear surface into two areas in an electrically insulated manner, n type layer electrodes 6 that are arranged on the n type diffusion layer 4 on the rear surface connected to the n type diffusion layer 4 on the light receiving surface through the side walls of the through holes 3, p type layer electrodes 8 that are arranged on the n type diffusion layer 4 connected to the p type polycrystalline silicon substrate 2 through p+ type diffusion layers 7, respectively, and an antireflection coating 9 that is formed on the surface of the n type diffusion layer 4 on the light receiving surface to serve for the purpose of prevention of reflection. In the following explanation, the surface of the p type polycrystalline silicon substrate 2 indicates the light receiving surface, the rear surface, and the surfaces of the side walls of the through holes 3.

The through holes 3 are each in the shape of a column having an inner diameter of about 100 μm with its openings in the light receiving surface and the rear surface of the p type polycrystalline silicon substrate 2 being substantially the same in size with each other. In the p type polycrystalline silicon substrate 2, there are machine formed a multitude of through holes 3 in a grid-like manner with rows and columns being both arranged at a pitch of 1.5 mm, as shown in FIG. 2. Though the side walls of the through holes 3 rise steeply substantially vertically with respect to the light receiving surface, the effects of the present invention can be achieved even if the area of one of the openings is slightly larger than that of the other due to laser processing.

The n type diffusion layers 4 have phosphorus diffused therein, so they have different sheet resistances that vary according to their locations. The rear surface and the side walls of the through holes 3 have their sheet resistance kept as formed in a pn junction forming step, and the sheet resistance is about 30Ω/□, and the thickness of the n type diffusion layers 4 in these portions is about 1 μm. On the other hand, etchback processing is applied to the light receiving surface after the pn junction forming step, so that the light receiving surface has its sheet resistance adjusted to meet an optimal sheet resistance for a photoelectromotive force to be generated. The sheet resistance is about 50 to 60Ω/□, and the thickness of the n type diffusion layer 4 in this portion is 0.4 to 0.5 μm.

As shown in FIG. 2, the grooves 5 serve to divide the n type diffusion layers 4 formed on the rear surface of the p type polycrystalline silicon substrate 2 into first regions 11 in each of which a group of through holes 3 of a corresponding row are included and in each of which there are formed n type layer electrodes 6 connected to the n type diffusion layers 4 on the light receiving surface through the n type diffusion layers 4 on the side walls of the through holes 3, and second regions 12 in which the p type layer electrodes 8 are formed. Here, note that the first regions 11 are provided for individual rows, respectively.

The grooves 5 each have a width of 20 to 40 μm and a depth of a few μm to 50 μm, and serve to electrically insulate the first regions 11 of the n type diffusion layer 4 on the rear surface, each of which has a thickness of 1 μm, and the second regions 12 from each other.

The p+ type diffusion layers 7 penetrate through the n type diffusion layers 4 in the second regions 12 to connect the p type layer electrodes 8 and the p type polycrystalline silicon substrate 2 to each other. The p+ type diffusion layers 7 are formed by the diffusion of aluminum atoms through the n type diffusion layers 4 up to the p type polycrystalline silicon substrate 2 during the baking of silver aluminum which is used to form the p type layer electrodes 8.

As shown in FIG. 3, the n type layer electrodes 6 are each composed of surrounding portions 13 that are formed on the n type diffusion layer 4 of the rear surface around the openings of corresponding through holes 3 opened on the rear surface, and a column portion 14 that connects the individual surrounding portions 13 in each column with one another. The n type layer electrodes 6 exert conduction when glass frits melt to connect individual silver powders with one another.

The p type layer electrodes 8 are arranged in parallel to the column portions of the corresponding n type layer electrodes 6, and exhibit conduction when the glass frits melt to connect silver aluminum alloy or aluminum powders with one another.

As materials for the antireflection coating 9, there can be used an Si₃N₄ film, a TiO₂ film, an SiO₂ film, an MgO film, an ITO film, an SnO₂ film, a ZnO film, and so on. In general, the Si₃N₄ film is preferably used because of its passivation property and a source or raw gas in the form of a mixed gas of silane and ammonia is made plasma by RF, micro waves, etc., so that Si₃N₄ is generated to form the antireflection coating 9.

Here, note that the thickness of the antireflection coating 9 may be arbitrarily selected according to the material to be used so as to achieve a reflectionless condition of incident light. That is, assuming that the refractive index of the material to be used is n and the wavelength of a spectral range that is to be made reflectionless is λ, d that satisfies (λ/n)/4=d becomes an optimal film thickness of the antireflection coating 9. For example, in case of the Si₃N₄ film (n=about 2) generally used, assuming that a reflectionless target wavelength is 600 nm, the film thickness may be set to about 75 nm.

Now, reference will be made to a solar battery 15 that is assembled using the above-mentioned solar battery cells 1 while referring to FIG. 4.

The filler film 16 and a glass plate 17 are sequentially laminated on the light receiving surface of each solar battery cell 1. The interconnection of adjacent cells by means of copper foils are carried out after the solar battery cells are adhered to the glass plate, as shown in FIG. 4. In a past solar battery, the glass plate was adhered to solar battery cells after the interconnection thereof by soldering. In the conventional case, a warp is generated by a difference in expansion coefficients of the copper foils and the silicon solar battery, and the thinner the thickness of silicon, the warp becomes larger, thereby causing cracks, so it has been practically difficult to perform such interconnection by the copper foils when the thickness of silicon is less than 150 μm. However, in case of the present invention, the solar battery cells, after having been adhered to the glass plate, are interconnected with one another. The ordinary glass plate has a thickness of 3.2 mm, and has sufficient rigidity with respect to the difference in the coefficients of thermal expansion between itself and the copper foils, as a result of which even if the thickness of each solar battery cell is made thin, no warp will be generated and hence no crack will occur. In addition, the interconnection can be made on the rear surface alone, so there is no need to arrange copper foils from the front side to the rear side, as in the conventional solar battery, whereby it has become possible to simplify the process of the interconnection.

Next, reference will be made to a method of producing the solar battery cells 1 according to the first embodiment of the present invention while referring to FIG. 5.

First of all, a substrate slicing process is performed. That is, a p type polysilicon ingot is sliced to prepare a p type polycrystalline silicon substrate 2 having a thickness of 50 to 200 μm and an outer shape of a 15×15 cm square.

Then, as shown in FIG. 5(a), a through hole forming process is performed to form a plurality of through holes 3 in the p type polycrystalline silicon substrate 2. In this through hole forming step, a YAG laser, in which neodymium excited by a laser diode is added as an activated atom, or a YVO4 laser, in which neodymium is added as an activated atom, is used. By irradiating a laser beam having a wavelength of 355 nm and a pulse width of less than 100 nsec such as, for example, 10 to 40 nsec by the use of the laser diode excited solid state laser, a multitude of through holes 3 are perforated through the p type polycrystalline silicon substrate 2 in a grid-like manner with its rows and columns being both arranged at a pitch of 1.5 mm. Each of the through holes 3 is of a columnar shape having an inner diameter of 100 μm. The processing rate is 0.5 to 1 μm per pulse, so when the repetition frequency of the laser is set to 10 kHz, the time required to form a through hole 3 in the p type polycrystalline silicon substrate 2 of 50 to 200 μm thick is within 0.1 seconds.

Subsequently, a damaged layer removing process is performed. In this damaged layer removing process, to remove a machined quality-changed layer and smudges on the surface of the p type polycrystalline silicon substrate 2 generated in the substrate slicing process, the surface of the p type polycrystalline silicon substrate 2 is etched by about from 5 to 20 μm by using an alkaline aqueous solution such as a potassium hydroxide aqueous solution, a sodium hydroxide aqueous solution, etc., or a mixed liquid of hydrofluoric acid, nitric acid, etc.

Thereafter, a texture forming process is performed, as shown in FIG. 5(b). In this texture forming process, irregularities called a texture structure are formed on the light receiving surface of the p type polycrystalline silicon substrate 2.

The formation of the texture structure is made by a light confinement technique utilizing the multiple reflection of incident light, and is carried out to enhance the performance of the solar battery. In order to obtain such a texture structure, there is performed, for example, a method utilizing wet etching that uses a solution in which isopropyl alcohol of 1 to 30 weight percent is added to an alkaline solution similar to the one used in the damaged layer removing process, a sodium carbonate (Na₂CO₃) solution, etc., or a method of machining grooves in a mechanical way, or the like.

Then, a pn junction forming process is carried out, as shown in FIG. 5(c). In this pn junction forming process, on the p type polycrystalline silicon substrate 2, there is formed the n type diffusion layer 4, which is of a reversed electrical conductivity type, by thermally diffusing phosphorus therein. A method of forming the n type diffusion layer 4 uses thermal diffusion by phosphorus oxychloride (POCl₃). As another method, impurities including phosphorus is attached to the surface of the p type polycrystalline silicon substrate 2 and is caused to thermally diffuse therein according to an appropriate method by using, as a supply source, an SOD (Spin-On-Dopant), a PSG (Phospho-Silicate-Glass), a phosphoric acid type solution, a film diffusion source, etc.

Subsequently, only the surface of each cell is etched back. First of all, the etching of the phosphorus glass remaining on a surface of the p type polycrystalline silicon substrate 2 after diffusion thereof on the front side thereof is performed by RIE etching for instance. According to this, a gas is introduced into an evacuated chamber, held at a fixed pressure, and is caused to generate a plasma by impressing an RF electric power to electrodes arranged in the chamber, so that the phosphorus glass on the light receiving surface of the p type polycrystalline silicon substrate 2 is etched by the action of ion radicals and the like thus generated which are active species. This method is called a reactive ion etching (RIE) method.

For example, in a reactive ion etching apparatus, etching is performed for a predetermined time by impressing RF electric power while supplying chlorine (Cl₂), oxygen (O₂) and sulfur hexafluoride (SF₆) at a ratio of 1:5:5 to generate a plasma and adjusting the reactive pressure to 7 Pa.

Under such a condition, only the phosphorus glass layer on the light receiving surface side is removed.

Thereafter, an etchback process is carried out. In the etchback process, a high density impurity region is removed by dipping or soaking the n type diffusion layer 4 on the light receiving surface into a mixed aqueous solution of hydrofluoric acid and a hydrogen peroxide solution. This etchback process includes two step processes comprising an oxidation process of oxidizing silicon with the hydrogen peroxide solution, and an etching process of etching a silicon oxide film with the hydrofluoric acid.

Then, a phosphorus glass removing process is carried out. The phosphorus glass remaining on the surface of the p type polycrystalline silicon substrate 2 after diffusion thereof can be removed in a short period of time by soaking it in the hydrofluoric acid solution. Here, note that the phosphorus glass represents a compound containing phosphorus and oxygen or a residual substance of the diffusion source. Under such a condition, the sheet resistance of the front surface side can be adjusted to 100Ω/□, and the sheet resistance of the n type layers on the side surface of each through hole and on the rear surface can be both adjusted to 30Ω/□.

Subsequently, an antireflection coating forming process is carried out. In this antireflection coating forming process, an insulating film in the form of the antireflection coating 9 is formed on the light receiving surface of the p type polycrystalline silicon substrate 2. The insulating film, which constitutes this antireflection coating 9, becomes possible to increase generation current so as to reduce the surface reflection rate of the solar battery with respect to incident light. For example, in case where a silicon nitride film is applied to the antireflection coating 9, it is formed by using a decompression thermal CVD method or a plasma CVD method as a method of formation thereof. In case of the decompression thermal CVD method, dichlorosilane (SiC₁₂H₂) and ammonia (NH₃) are often used as raw materials, and deposition is made, for example, under the condition that the gas flow rate ratio of NH₃ to SiC₁₂H₂ is equal to 10 to 20, the pressure in the reaction chamber is 2×10⁴ Pa to 5×10⁴ Pa, and the temperature is 760° C. In addition, it is general to use a mixed gas of SiH₄ and NH₃ as a source gas in case of the deposition being made by the plasma CVD method. As a deposition condition, for example, the following is appropriate: the gas flow rate ratio of NH₃/SiH₄ is equal to 0.5 to 1.5; the pressure in the reaction chamber is 1×10⁵ Pa to 2×10⁵ Pa; the temperature is 300° C. to 550° C.; the frequency of high frequency power source required for plasma discharge is a few hundreds kHz or more.

Then, a pn isolation or separation process is carried out, as shown in FIG. 5(d). In the pn isolation process, the grooves 5 having a width of 20 to 40 μm and a depth of a few μm to 50 μm are formed so as to enclose the surroundings of the individual columns of the through holes 3, respectively, on the rear surface of the p type polycrystalline silicon substrate 2 by means of a laser beam having a wavelength of 355 nm and a pulse width of less than 100 nsec, e.g., 10 to 40 nsec. As a result, the first regions 11 of the n type diffusion layer 4, which form the n type layer electrodes 6, and the second regions 12 of the n type diffusion layer 4, which form the p type layer electrodes 8, are electrically insulated from each other.

Thereafter, an electrode forming process is carried out, as shown in FIG. 5(e). In the electrode forming process, silver pastes are first formed, by means of a screen printing technique, into predetermined pattern shapes on the first regions 11 forming the n type layer electrodes 6 including the surroundings of the openings of the through holes 3, and thereafter, the silver pastes thus formed are baked, for example, at a temperature of 650° C. to 900° C. for a period of time of a few tens of seconds to a few minutes to form the n type layer electrodes 6. The n type layer electrodes 6 are ohmic connected to the n type diffusion layers 4, respectively, by baking. The diffusion of the components constituting the n type layer electrodes 6 is limited to within the n type diffusion layers 4.

Subsequently, silver aluminum pastes are formed, by the screen printing technique, into predetermined pattern shapes on the second regions 12 forming the p type layer electrodes 8, and thereafter, baked for example at a temperature of 650° C. to 900° C. for a period of time of a few tens of seconds to a few minutes to form the p type layer electrodes 8. In the p type layer electrodes 8, aluminum atoms are diffused by baking into the n type diffusion layers 4 and the p type polycrystalline silicon substrate 2 to change the electric conductivity of the diffused portions into p+ type, whereby the p type layer electrodes 8 are ohmic connected to the p type polycrystalline silicon substrate 2. In this manner, the components constituting the p type layer electrodes 8 are diffused by baking into the p type polycrystalline silicon substrate 2 exceeding the thickness of the n type diffusion layers 4.

Thus, the solar battery cells 1 are produced.

Then, a light receiving surface protection process is carried out. In the light receiving surface protection process, a filler material layer 16 such as silicone resin is coated on the antireflection coating 9 so as to flatten the surface thereof, after which a glass plate 17 is laminated thereon, and the silicone resin is set or hardened to fix the glass plate 17.

Thereafter, the solar battery cells 1 which are adjacent to one another at the rear surface side alone are mutually interconnected with one another. In this manner, the solar battery 15 is prepared.

Next, reference will be made to the condition of the laser processing by which the grooves 5 are formed on the rear surface to provide pn isolation. The electrical characteristics of the solar battery 15 can be represented by an equivalent circuit shown in FIG. 6. The equivalent circuit is composed of a photoelectromotive current source (I_{L}), a diode, a series resistor (r_{S}), and a parallel resistor (r_{Sh}), wherein the series resistor (r_{S}) represents an ohmic loss of the light receiving surface of the solar battery 15, and the parallel resistor (r_{Sh}) represents a loss due to a diode leakage current. A determination as to whether the pn isolation has been effected adequately may be made based on the resistance of the parallel resistor (r_{Sh}) or a diode current I_{d} obtained upon application of a reverse bias. It means that the smaller the diode current I_{d} upon application of the reverse bias, the smaller the leakage is, and hence the better the electric insulation is. In FIG. 7, there is shown the relation between the pulse width of the laser beam used for laser processing of the grooves 5 and the diode current I_{d} in the solar battery of 15 cm square upon impression of a reverse bias (−1 V). As can be seen from FIG. 7, when the pulse width is 100 nsec or less, the diode current I_{d} becomes 0.1 A or less and hence the electrical insulation is excellent. On the other hand, it is found that when the pulse width exceeds 100 nsec, the diode current I_{d} increases and the electrical insulation deteriorates. It appears that this is because when the pulse width becomes large, melting occurs in the vicinity of processed portions, thus deteriorating the electrical insulation.

In addition, as another laser processing condition associated with the electrical isolation, there is radiation energy other than the pulse width. When the radiation energy is low, the laser processing becomes unsatisfactory, whereas when the radiation energy is too high, melting occurs to worsen the electric insulation. Even when the wavelength of the laser beam is a fundamental wavelength of 1064 nm or is a third harmonic component of 355 nm, a condition that improves the electric insulation was that the radiation energy per unit area per pulse is from 10 J/Pulse·cm² to 30 J/Pulse·cm².

In addition, the groove processing is performed by moving radiation spots partially overlapped with each other, and the overlapping rate of the radiation spots becomes 60% or more.

Such a solar battery 15 has the through holes 3 formed in the grid-like fashion, the side walls of which rise substantially perpendicularly to the thickness direction of the semiconductor substrate and which are circular in cross section, with the pn junction of the light receiving surface being connected to the n type layer electrodes 6 on the rear surface through the n type diffusion layers 4 on the side walls of the through holes 3. Accordingly, the decrease of the plane of incidence is reduced due to the provision of the through holes 3, so the amount of electric power generation per area increases.

Moreover, the shapes of the through holes 3 are uniformly formed, so dimensional margins between the n type layer electrodes and the p type layer electrodes in consideration of the variation of the shapes of the through holes 3 can be decreased, thus making it possible to increase the size of the electrodes.

Further, the n type diffusion layers 4 formed on the side walls of the through holes 3 are cylindrical, and hence are smaller in resistance than pyramidal cylinders which are formed according to an anisotropic etching method. As a result, the solar battery cells 1 with high power generation efficiency can be provided.

Furthermore, even if the semiconductor substrate is thick, it is possible to form the through holes 3 of a large aspect ratio by applying a laser-diode-pumped solid state laser to the processing of the through holes 3. Accordingly, it is possible to use an inexpensive semiconductor substrate, which can be obtained by slicing an ingot, instead of using a semiconductor substrate which can be produced only by the use of a method including a lot of the number of processes.

In addition, the melting of silicon can be prevented by performing groove processing by the use of a laser beam having a pulse width of 100 nsec or less, so it is possible to provide the solar battery cells 1 that have an excellent electric insulating property.

Also, by performing the groove processing by the radiation of a laser beam having a radiation energy density per pulse of from 10 J/Pulse·cm² or more to less than 30 J/Pulse·cm², it is possible to carry out appropriate processing without causing the melting of silicon. As a result, it is possible to provide a solar battery that has an excellent electric insulating property.

Moreover, soldering is effected on the rear surface alone after the glass plate 17 is adhered to the light receiving surface by the filler material layer 16, so the semiconductor substrate is supported by the glass plate 17, causing no problem of warping. In particular, even if the thickness of the semiconductor substrate becomes less than 150 μm, stress is born by the glass plate 17, so the cells can be modularized without causing any cell crack. On the other hand, when copper foils are connected to the n type layer electrodes of the light receiving surface and the p type layer electrodes of the rear surface, respectively, the stress due to a difference in the coefficient of thermal expansion between copper and silicon is applied to the semiconductor substrate, whereby warping occurs, generating cell cracks. In particular, when the thickness of the semiconductor substrate becomes about 150 μm, a cell crack occurs, thus making the modularization difficult.

In addition, it becomes possible to perform assembling on the rear surface alone, so the assembling becomes easy.

### Embodiment 2

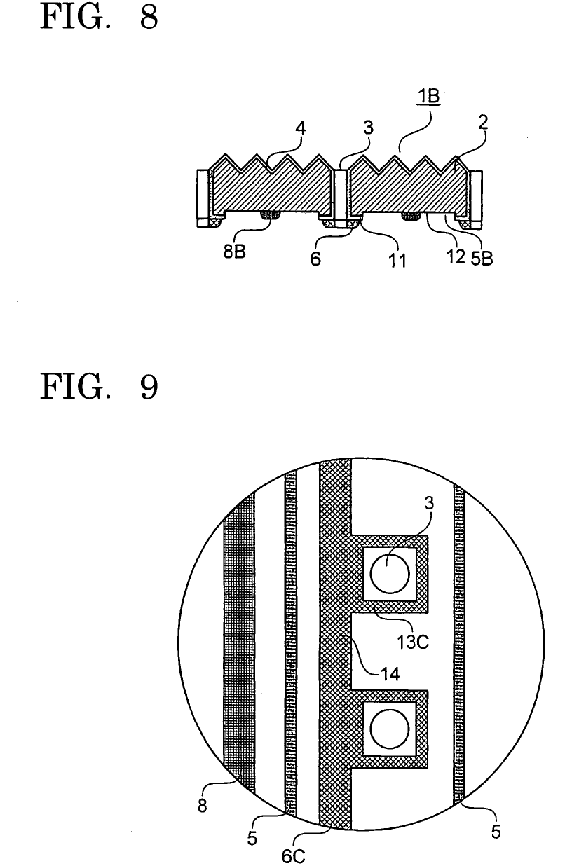

FIG. 8 is a partial cross sectional view of a solar battery cell according to a second embodiment of the present invention. A solar battery cell 1B according to the second embodiment is different from the former one in the following. That is, n type diffusion layers 4, being formed in the positions in which p type layer electrodes 8B are to be arranged, are removed so as to expose the p type polycrystalline silicon substrate 2 to the surface, as shown in FIG. 8, as a result of which there is no need to use the silver aluminum pastes used to form the p+ type diffusion layers 7 in the first embodiment, so the p type layer electrodes 8B can be formed together with the formation of n type layer electrodes 6 by means of screen printing. However, the other construction is similar, and hence like components or parts are identified by like symbols while omitting a detailed explanation thereof.

Since the width of the p type layer electrodes 8B is about 60 μm, the width of each groove 5B need be set to about 150 μm in consideration of the margin for position adjustment, and radiation need be effected while moving the position of laser radiation several times. Even if the width of each groove 5B is made wider in this manner, the time required for processing increases only slightly as a whole.

With such a solar battery cell 1B, the same electrode forming paste can be used for both the n type layer electrodes 6 and the p type layer electrodes 8B, and the positional adjustment of a screen need be effected only one time, so a more inexpensive solar battery can be provided.

### Embodiment 3

FIG. 9 is a layout view of electrodes on a rear surface of a solar battery cell according to a third embodiment. A solar battery cell according to the third embodiment is different from the solar battery cell 1 according to the first embodiment in the shape of an n type layer electrode 6C, but the other construction is similar, and hence like components or parts are identified by like symbols while omitting a detailed explanation thereof. The n type layer electrode 6C according to the third embodiment has a surrounding portion 13C enclosing an opening of a corresponding through hole 3 spaced apart from the peripheral portion of the opening by a predetermined distance, as shown in FIG. 9.

With such a solar battery cell, the n type layer electrode 6C is apart from the openings of the through holes 3, so when the n type layer electrodes 6C are formed by screen printing, a print paste does not flow into the through holes 3, as a consequence of which the print paste can be prevented from extending to the light receiving surface.

In addition, light hits the pn junctions of the through holes 3, too, so the through holes 3 also contribute to power generation.

1-13. (canceled)

14. A solar battery comprising:
a first semiconductor layer that is formed on a light receiving surface of a semiconductor substrate, and is of a type opposite to that of said semiconductor substrate;
a second semiconductor layer that is formed on a rear surface opposite to said light receiving surface, and is of the same type as that of said first semiconductor layer;
an electrode of a third semiconductor layer that is of the same type as that of the first semiconductor layer, and is formed on the second semiconductor layer;
a first electrode that is of the same type as that of said semiconductor substrate, and is directly formed on the rear surface of said semiconductor substrate so as to be electrically insulated from said electrode of the third semiconductor layer; and
a fourth semiconductor layer that is of the same type as that of the first semiconductor layer, and electrically connects between the first semiconductor layer and said electrode of the third semiconductor layer.

15. The solar battery as set forth in claim 14, wherein
the fourth semiconductor layer is formed on a wall surface of a through hole formed in said semiconductor substrate.

16. The solar battery as set forth in claim 15, wherein
the first semiconductor layer, the second semiconductor layer, and the fourth semiconductor layer are diffusion layers for said semiconductor substrate.

17. A solar battery comprising:
a first semiconductor layer that is formed on a light receiving surface of a semiconductor substrate, and is of a type opposite to that of said semiconductor substrate;
a second semiconductor layer that is formed on a rear surface opposite to said light receiving surface, and is of the same type as that of said first semiconductor layer;
an electrode of a third semiconductor layer that is formed on the second semiconductor layer, and is of the same type as that of the first semiconductor layer;
a fourth semiconductor layer that is formed on the rear surface of said semiconductor substrate so as to be electrically insulated from the second semiconductor layer, and is of the same type as that of said first semiconductor layer;
a first electrode that is of the same type as that of said semiconductor substrate, and penetrates through the fourth semiconductor layer to connect said semiconductor substrate; and
a fifth semiconductor layer that electrically connects between the first semiconductor layer and said electrode of the third semiconductor layer.

18. The solar battery as set forth in claim 17, wherein
the fifth semiconductor layer is formed on a wall surface of a through hole formed in said semiconductor substrate.

19. The solar battery as set forth in claim 18, wherein
the first semiconductor layer, the second semiconductor layer, the fourth semiconductor layer, and the fifth semiconductor layer are diffusion layers for said semiconductor substrate.

20. The solar battery as set forth in claim 19, wherein
a groove in which said diffusion layers are not arranged is formed so as to enclose said through hole and the second semiconductor layer.

21. The solar battery as set forth in claim 20, wherein
said first electrode is arranged outside said groove.

22. A method of producing a solar battery, comprising:
a step of forming a through hole in a semiconductor substrate;
a step of forming on light-emitting surface of said semiconductor substrate and a wall surface of said through hole a first semiconductor layer that is of a type opposite to that of said semiconductor substrate; and
a step of forming on a rear surface of said semiconductor substrate an electrode of a second semiconductor layer of the same type as that of the first semiconductor layer so as to electrically connect to the first semiconductor layer formed on the wall surface of said through hole, and forming on the rear surface of said semiconductor substrate a first electrode that is of the same type as that of said semiconductor substrate so as to be electrically insulated from said electrode of the second semiconductor layer.

23. The method as set forth in claim 22, wherein
the step of forming on the light receiving surface of said semiconductor substrate and the wall surface of said through hole the first semiconductor layer that is of the type opposite to that of said semiconductor substrate includes a step of forming the first semiconductor layer on the rear surface of said semiconductor substrate; and
the step of forming on the rear surface of said semiconductor substrate said electrode of the second semiconductor layer of the same type as that of the first semiconductor layer so as to electrically connect to the first semiconductor layer formed on the wall surface of said through hole, and forming on the rear surface of said semiconductor substrate the first electrode that is of the same type as that of said semiconductor substrate so as to be electrically insulated from said electrode of the second semiconductor layer includes a step of forming a groove in which said first semiconductor layer formed on the rear surface of said semiconductor substrate is removed so as to enclose said through hole; a step of forming said electrode of the second semiconductor layer in a region enclosed by said groove; and a step of forming said first electrode outside the region enclosed by said groove.

24. The method of producing a solar battery as set forth in claim 23, wherein the step of forming the through hole in said semiconductor substrate includes a step of radiating a laser beam.

25. The method of producing a solar battery as set forth in claim 23, wherein the step of forming said groove in which said first semiconductor layer formed on the rear surface of said semiconductor substrate is removed so as to enclose said through hole includes a step of radiating a pulsed laser beam having a pulse width of 100 nsec or less.

26. The method of producing a solar battery as set forth in claim 24, wherein said laser beam has an energy density per pulse of 10 J/Pulse·cm² to 30 J/Pulse·cm².
